(19) United States
(12) Patent Application Publication
(10) Pub. No.: US 2020/0211872 A1
(43) Pub. Date: Jul. 2, 2020

(54) TEMPERATURE CONTROLLING APPARATUS AND METHOD OF CONTROLLING THE TEMPERATURE CONTROLLING APPARATUS

(71) Applicant: Tokyo Electron Limited, Tokyo (JP)

(72) Inventor: Kei KOBAYASHI, Miyagi (JP)

(21) Appl. No.: 16/714,910

(22) Filed: Dec. 16, 2019

(30) Foreign Application Priority Data
Dec. 26, 2018 (JP) 2018-243709

(51) Int. Cl. H01L 21/67; H01J 37/32

(52) U.S. Cl. CPC H01L 21/67248; H01J 37/32724; H01L 21/67109

(57) ABSTRACT

A temperature controlling apparatus includes a member having a member flow path within the member, and includes a first temperature controller configured to control a temperature of a first temperature-controlled medium to a first temperature. The temperature controlling apparatus includes a second temperature controller configured to control a temperature of a second temperature-controlled medium to a second temperature, the second temperature differing from the first temperature. The temperature controlling apparatus includes a first flow path of the first temperature-controlled medium, between the member flow path and the first temperature controller. The temperature controlling apparatus includes a second flow path of the second temperature-controlled medium, between the member flow path and the second temperature controller, and includes a third flow path of the first temperature-controlled medium that flows to the first temperature controller, without using the member flow path.

### CROSS-REFERENCE TO RELATED APPLICATION

This patent application claims priority to Japanese Patent Application No. 2018-243709, filed Dec. 26, 2018, the entire contents of which are incorporated herein by reference in their entirety.

### TECHNICAL FIELD

The present disclosure relates to a temperature controlling apparatus and a method of controlling the temperature controlling apparatus.

### BACKGROUND

Under multiple process conditions, a chiller unit needs a technique of changing a temperature of a heat medium such as brine, globally and speedily.

Japanese Translation of PCT International Application Publication No. 2013-534716, which is referred to as Patent document 1, discloses a recirculation system having multiple switching valves.

### SUMMARY

In one aspect, the present disclosure provides a temperature controlling apparatus and a method of controlling the temperature controlling apparatus, so as to reduce the number of valves.

According to one aspect, a temperature controlling apparatus is provided, including: a member having a member flow path within the member; a first temperature controller configured to control a temperature of a first temperature-controlled medium to a first temperature; a second temperature controller configured to control a temperature of a second temperature-controlled medium to a second temperature, the second temperature differing from the first temperature; a first flow path of the first temperature-controlled medium, between the member flow path and the first temperature controller; and a second flow path of the second temperature-controlled medium, between the member flow path and the second temperature controller. The temperature controlling apparatus includes a third flow path of the first temperature-controlled medium that flows to the first temperature controller, without using the member flow path; and a fourth flow path of the second temperature-controlled medium that flows to the second temperature controller, without using the member flow path. The temperature controlling apparatus includes a first three-way valve configured to switch a flow between the first flow path and the third flow path; a second three-way valve configured to switch a flow between the second flow path and the fourth flow path; and a third three-way valve configured to switch a flow between the first flow path and the second flow path.

### BRIEF DESCRIPTION OF THE DRAWINGS

FIGS. 1A and 1B are diagrams illustrating an example of a configuration of a temperature controlling apparatus according to a first embodiment;

FIG. 2 is a time chart for explaining an example of a switching process by the temperature controlling apparatus according to the first embodiment;

FIGS. 3A and 3B are diagrams illustrating a configuration of a temperature controlling apparatus in a first reference example;

FIG. 4 is a time chart for explaining a switching process by the temperature controlling apparatus in the first reference example;

FIGS. 5A and 5B are diagrams illustrating a configuration of a temperature controlling apparatus in a second reference example;

FIG. 6 is a time chart for explaining a switching process by the temperature controlling apparatus in the second reference example;

FIGS. 7A and 7B are diagrams illustrating an example of a configuration of a temperature controlling apparatus according to a second embodiment;

FIG. 8 is a time chart for explaining an example of a switching process by the temperature controlling apparatus according to the second embodiment;

FIG. 9 is a diagram illustrating an example of engaging a third mode operation in the temperature controlling apparatus according to the first embodiment; and

FIG. 10 is a diagram illustrating an example of engaging a third mode operation in the temperature controlling apparatus according to the second embodiment.

### DESCRIPTION OF THE PREFERRED EMBODIMENTS

Embodiments will be explained hereinafter with reference to the drawings. In each drawing, the same reference numerals are used to denote same components; accordingly, duplicative explanations may be omitted for the same components.

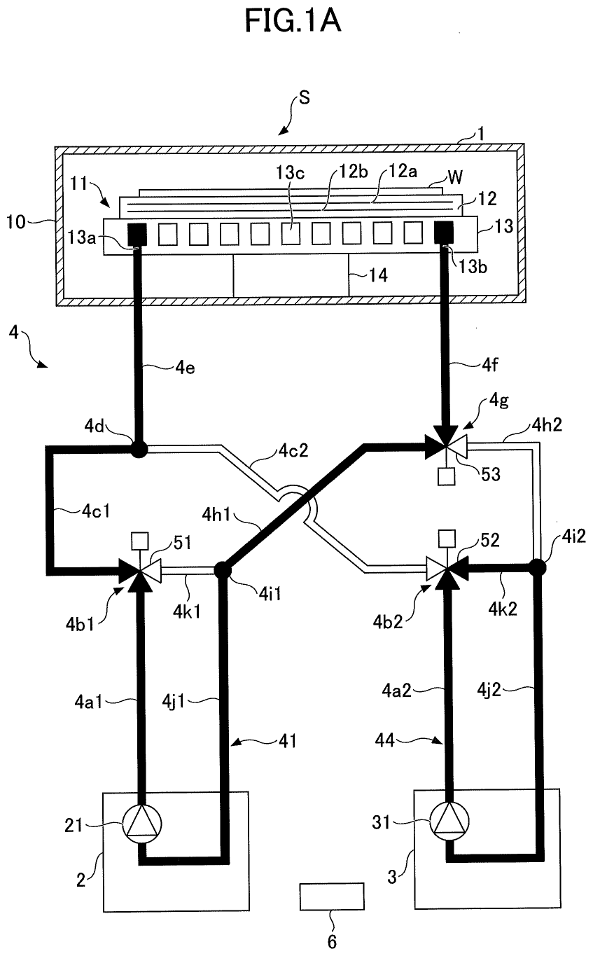

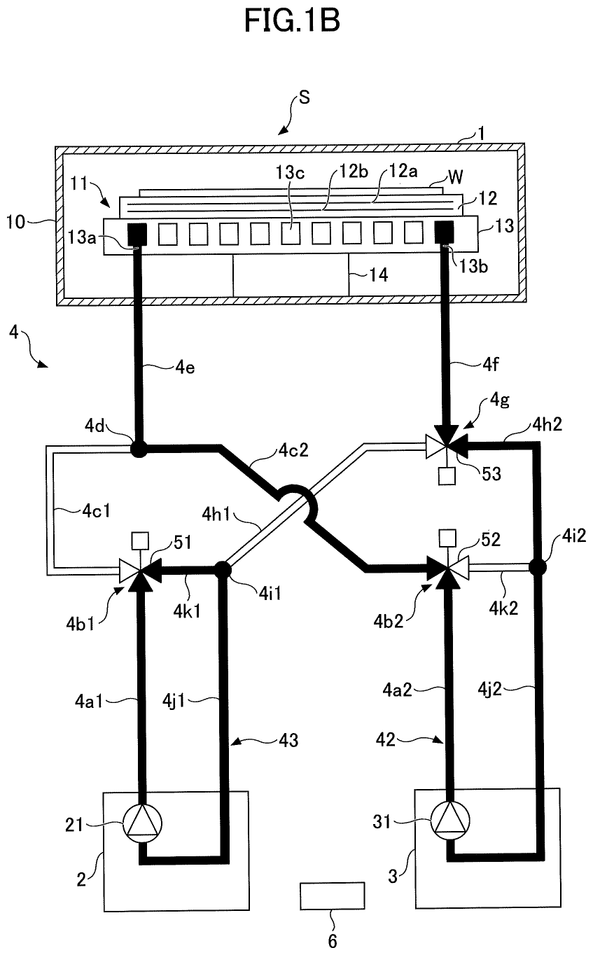

A temperature controlling apparatus S according to a first embodiment will be described with reference to FIGS. 1A and 1B. FIGS. 1A and 1B are diagrams illustrating a configuration of the temperature controlling apparatus S according to the first embodiment. FIG. 1A illustrates an example of engaging a first mode operation, and FIG. 1B illustrates an example of engaging a second mode operation.

The temperature controlling apparatus S according to the first embodiment includes a processing device 1, a first chiller 2, a second chiller 3, and a flow path 4. The temperature controlling apparatus S includes three-way valves 51, 52, and 53 that are provided in the flow path 4, and includes a control device 6.

The processing device 1 is a device for processing a wafer W. The wafer W is subjected to heat treatment, plasma treatment, UV treatment, and other treatments. Processing of the wafer W includes various processes such as etching, film formation, cleaning, treatment, and ashing.

The processing device 1 includes a processing chamber 10 and a stage 11 for mounting a wafer W. The stage 11 includes an electrostatic chuck 12 and a base (member) 13. The electrostatic chuck 12 is disposed on the base 13. The electrostatic chuck 12 includes an electrode 12a and a heater 12b. When a DC (direct current) power supply applies a voltage to the electrode 12a, the wafer W is electrostatically absorbed onto the electrostatic chuck 12. When an AC (alternating current) power supply applies a voltage to the heater 12b, the wafer W can be heated. Note that the electrode 12a and the heater 12b are each controlled by the control device 6 to be energized. The base 13 is supported by a support stand 14. Within the base 13, a member flow path 13c, which has an inlet 13a on one side thereof; and an outlet 13b on another side, is formed in an annular pattern or a volute pattern. The support stand 14 supports the base 13 within the processing chamber 10.

As the processing device 1, a plasma processing device may be used. A radio frequency power source (not shown), which applies radio frequency power for plasma generation through a matching device (not shown), is connected to the base 13. In such a manner, the stage 11 serves as a lower electrode. Also, a gas supply source (not shown), which supplies desired gas to the processing chamber 10, and a vacuum pump (not shown), which depressurizes the processing chamber 10, are connected to the processing chamber 10. Within the processing chamber 10, a showerhead (not shown) is provided above the stage 11 to face the stage 11, and serves as an upper electrode. Plasma is generated between the showerhead as an upper electrode and the stage 11 as a lower electrode.

Note that an example of a heat medium may include liquid such as cooling water or brine; or gas such as coolant gas.

The first chiller 2 controls a temperature of a heat medium to a first temperature. The first chiller 2 includes a temperature controller (not shown) that controls a temperature of a heat medium; a tank (not shown) for storing a heat medium; and a pump 21 for discharging a heat medium. A temperature of a heat medium flowing into the first chiller 2 is controlled to a first temperature by the temperature controller such as a heat exchanger, and is stored in the tank. The pump 21 discharges a heat medium of which a temperature is controlled to a first temperature. Note that the heat medium that is discharged from the first chiller 2 and of which a temperature is controlled to a first temperature is also referred to as a first temperature-controlled medium. The first chiller 2 is an example of a first temperature controller configured to control a temperature of a first temperature-controlled medium to a first temperature.

The second chiller 3 controls a temperature of a heat medium to a second temperature that is different from a first temperature. The second chiller 3 includes a temperature controller (not shown) that controls a temperature of a heat medium; a tank (not shown) for storing a heat medium; and a pump 31 for discharging a heat medium. A temperature of the heat medium flowing into the second chiller 3 is controlled to a second temperature by the temperature controller such as a heat exchanger, and is stored in the tank. The pump 31 discharges a heat medium of which a temperature is controlled to a second temperature. Note that the heat medium of which a temperature is controlled to a second temperature and that is discharged from the second chiller 3 is also referred to as a second temperature-controlled medium. The second chiller 3 is an example of a second temperature controller configured to control a temperature of a second temperature-controlled medium to a second temperature that is different from the first temperature.

Note that an adjusting mechanism (not shown) for adjusting an amount of a heat medium may be disposed between the tank of the first chiller 2 and the tank of the second chiller 3. For example, the adjusting mechanism allows a heat medium to flow from one tank to another tank, when an amount of the heat medium stored in the one tank exceeds a predetermined amount.

The flow path 4 couples a member flow path 13c within the stage 11, the first chiller 2, and the second chiller 3, and allows for a flow of a heat medium. The flow path 4 includes a first flow path 41, a second flow path 42, a third flow path 43, and a fourth flow path 44. Note that the flow paths 41, 42, 43, and 44 included in the flow path 4 are achieved by pipes.

The first flow path 41 is a flow path through which a heat medium flows between the member flow path 13c and the first chiller 2. The first flow path 41 includes a flow path 4a1 coupling from a discharge side of the first chiller 2 to an inlet port of a three-way valve 51. The first flow path 41 includes a coupler 4b1, a flow path 4c1, a coupler 4d, and a flow path 4e. The first flow path 41 includes a flow path 4f coupling from an outlet 13b of the member flow path 13c to an inlet port of a three-way valve 53. The first flow path 41 includes a coupler 4g, a flow path 4h1, a coupler 4i1, and a flow path 4j1.

The second flow path 42 is a flow path through which a heat medium flows between the member flow path 13c and the second chiller 3. The second flow path 42 includes a flow path 4a2 coupling from a discharge side of the second chiller 3 to an inlet port of a three-way valve 52. The second flow path 42 includes a coupler 4b2, a flow path 4c2, the coupler 4d, and the flow path 4e. The second flow path 42 includes the flow path 4f coupling from the outlet 13b of the member flow path 13c to the inlet port of the three-way valve 53. The second flow path 42 includes a coupler 4g, a flow path 4h2, a coupler 4i2, and a flow path 4j2.

The third flow path 43 is a flow path through which a heat medium is cycled by the first chiller 2, without using the member flow path 13c. The third flow path 43 includes a flow path 4a1 coupling from the discharge side of the first chiller 2 to the inlet port of the three-way valve 51. The third flow path 43 includes the coupler 4b1, a flow path 4k1, the coupler 4i1, and a flow path 4j1.

The fourth flow path 44 is a flow path through which a heat medium is cycled by the second chiller 3, without using the member flow path 13c. The fourth flow path 44 includes the flow path 4a2 coupling from the discharge side of the second chiller 3 to the inlet port of the three-way valve 52. The fourth flow path 44 includes the coupler 4b2, a flow path 4k2, the coupler 4i2, and the flow path 4j2.

The three-way valve 51 has one inlet port and two outlet ports. The three-way valve 51 is configured such that, as a degree of opening of one outlet port increases, a degree of opening of the other outlet port is decreased. The three-way valves 52 and 53 each have the same configuration as the three-way valve 51.

The three-way valve 51 is disposed at the coupler 4b1. In this case, with respect to the three-way valve 51, the inlet port is coupled to the flow path 4a1, one outlet port as a first outlet port is coupled to the flow path 4c1; and another outlet port as a second outlet port is coupled to the flow path 4k1. In such a manner, the three-way valve 51 can switch a flow of a first temperature-controlled medium, between the first flow path 41 and the third flow path 43.

The three-way valve 52 is disposed at the coupler 4b2. In this case, with respect to the three-way valve 52, the inlet port is coupled to the flow path 4a2; one outlet port as a first outlet port is coupled to the flow path 4c2; and another outlet port as a second outlet port is coupled to the flow path 4k2. In such a manner, the three-way valve 52 can switch a flow of a second temperature-controlled medium, between the second flow path 42 and the fourth flow path 44.

The three-way valve 53 is disposed at the coupler 4g. In this case, with respect to the three-way valve 53, the inlet port is coupled to the flow path 4f; one outlet port as a first outlet port is coupled to the flow path 4h1; and another outlet port as a second outlet port is coupled to the flow path 4h2. In such a manner, the three-way valve 53 can switch a flow of a heat medium that is delivered from the outlet 13b of the member flow path 13c, between the first flow path 41 and the second flow path 42.

The control device 6 controls switching of the three-way valves 51 to 53, so that modes of the temperature controlling apparatus S are switched.

As illustrated in FIG. 1A, in a first mode operation, the three-way valve 51 is switched to open the first outlet port; the three-way valve 52 is switched to open the second outlet port; and the three-way valve 53 is switched to open the first outlet port. Thereby, the first flow path 41 is provided and thus a first temperature-controlled medium is supplied to the member flow path 13c. Further, the fourth flow path 44 is provided and thus a second temperature-controlled medium is cycled through the fourth flow path 44, by the second chiller 3.

As illustrated in FIG. 1B, in a second mode operation, the three-way valve 51 is switched to open the second outlet port; the three-way valve 52 is switched to open the first outlet port; and the three-way valve 53 is switched to open the second outlet port. Thereby, the second flow path 42 is provided and thus a second temperature-controlled medium is supplied to the member flow path 13c. Further, the third flow path 43 is provided and thus a first temperature-controlled medium is cycled through the third flow path 43, by the first chiller 2.

As described above, in the temperature controlling apparatus S according to the first embodiment, the three-way valves 51 to 53 are switched so that a temperature of a given heat medium that is supplied to the member flow path 13c can be thereby adjusted.

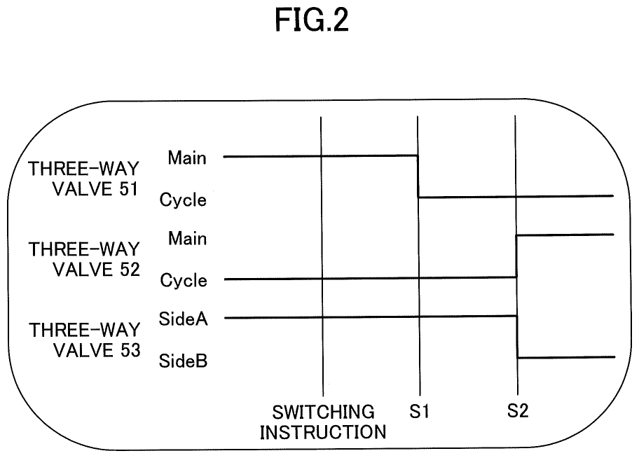

Hereafter, a switching process performed by the temperature controlling apparatus S according to the first embodiment will be described with reference to FIG. 2. FIG. 2 is a time chart for explaining an example of a switching process by the temperature controlling apparatus S according to the first embodiment.

In this description, a case where a state (see FIG. 1A) in which a first temperature-controlled medium is supplied to the member flow path 13c is changed to a state (see FIG. 1B) in which a second temperature-controlled medium is supplied will be described as an example.

Upon receiving a switching instruction, in step S1, the control device 6 causes the three-way valve 51 to switch a flow from a first flow path 41 (main) to a third flow path 43 (cycle).

In step S2, the control device 6 causes the three-way valve 52 to switch a flow from a fourth flow path 44 (cycle) to a second flow path 42 (main). The control device 6 also causes the three-way valve 53 to switch a flow from the first flow path 41 (side A) to the second flow path 42 (side B).

In step S1, in a case of the three-way valve 51 not operating, a flow path through a pump 21 is maintained as the first flow path 41. Thereby, the flow path through the pump 21 can be prevented from being shut off.

In step S2, in a case of the three-way valve 52 not operating, a flow path through a pump 31 is maintained as the fourth flow path 44. Thereby, the flow path through the pump 31 can be prevented from being shut off. In a case of the three-way valve 52 operating but the three-way valve 53 not operating, a second temperature-controlled medium discharged from the pump 31 flows along a flow path 4a2 and then is directed toward a tank (not shown) of the first chiller 2, via a coupler 4b2; a flow path 4c2; a coupler 4d; a flow path 4e; a member path 13c; a flow path 4f; a coupler 4g; a flow path 4h1; a coupler 4i1; and a flow path 4j1. Thereby, the flow path through the pump 31 can be prevented from being shut off. Note that a heat medium flowing to a tank (not shown) of the first chiller 2 may be returned to a tank (not shown) of the second chiller 3, via an adjusting mechanism (not shown).

As described above, in the temperature controlling apparatus S according to the first embodiment, with the two steps being taken, water hammer caused by a blockage in the flow paths along which the pumps 21 and 31 are arranged can be avoided.

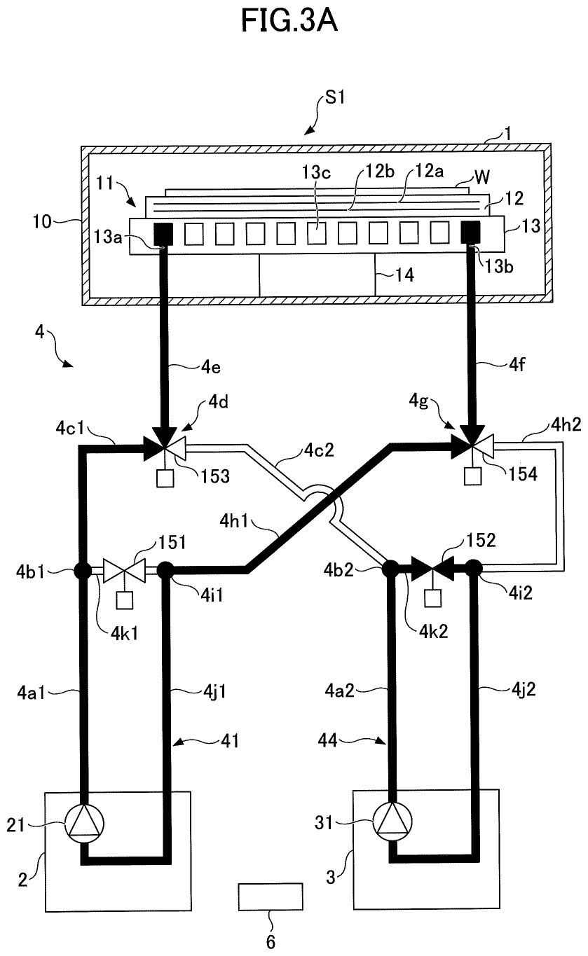

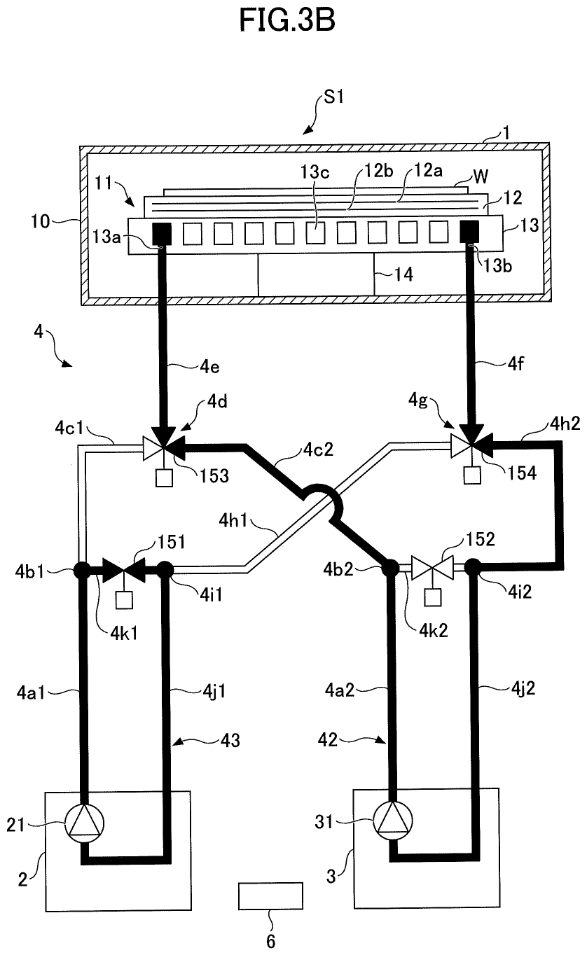

A temperature controlling apparatus S1 in a first reference example will be described with reference to FIGS. 3A to 6.

FIGS. 3A and 3B are diagrams illustrating a configuration of the temperature controlling apparatus S1 in the first reference example. FIG. 3A illustrates a first mode operation, and FIG. 3B illustrates a second mode operation.

In the first reference example, the temperature controlling apparatus S1 includes on-off valves 151 and 152 and three-way valves 153 and 154, instead of the three-way valves 51, 52, and 53 of the temperature controlling apparatus S according to the first embodiment. Other configurations are similar to the temperature controlling apparatus S; accordingly, duplicative explanations will be omitted for the configuration of the temperature controlling apparatus S1.

The on-off valve 151 is disposed in a flow path 4k1. The on-off valve 152 is disposed in a flow path 4k2. The three-way valve 153 is disposed at a coupler 4d. In this case, with respect to the three-way valve 153, one inlet port as a first inlet port is coupled to a flow path 4c1; another inlet port as a second inlet port is coupled to a flow path 4c2; and an outlet port is coupled to a flow path 4e. The three-way valve 154 is coupled at a coupler 4g. In this case, with respect to the three-way valve 154, an inlet port is coupled to a flow path 4f, one outlet port as a first outlet port is coupled to a flow path 4h1, and another outlet port as a second outlet port is coupled to a flow path 4h2.

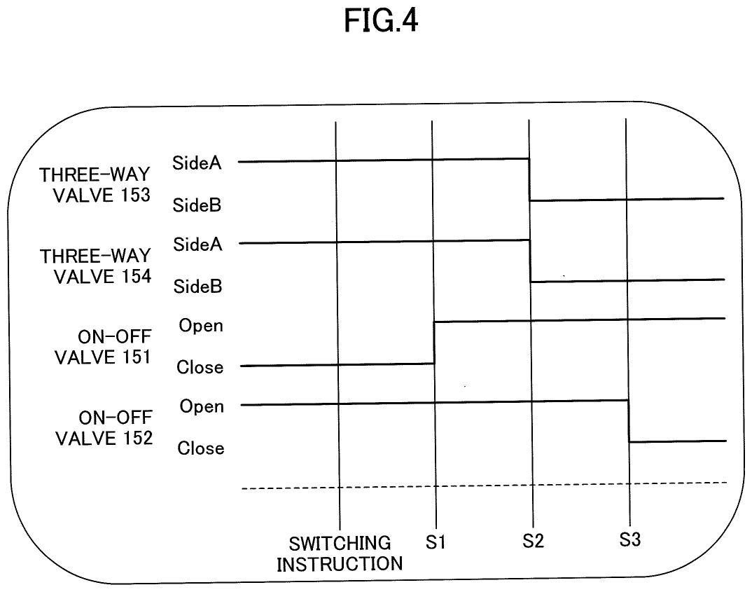

FIG. 4 is a time chart for explaining a switching process by the temperature controlling apparatus S1 in the first reference example.

Upon receiving a switching instruction, in step S1, a control device 6 causes the on-off valve 151 to switch from off (close) to on (open).

In step S2, the control device 6 causes the three-way valve 153 to switch a flow from a first flow path 41 (side A) to a second flow path 42 (side B). The control device 6 also causes the three-way valve 154 to switch a flow from the first flow path 41 (side A) to the second flow path 42 (side B).

In step S3, the control device 6 causes the on-off valve 152 to switch from on (close) to off (open).

As described above, in a manner such that the switching process is performed in order to avoid water hammer caused by a blockage in flow paths along which pumps 21 and 31 are arranged, the three steps are required to be taken by the temperature controlling apparatus S1 in the first reference example.

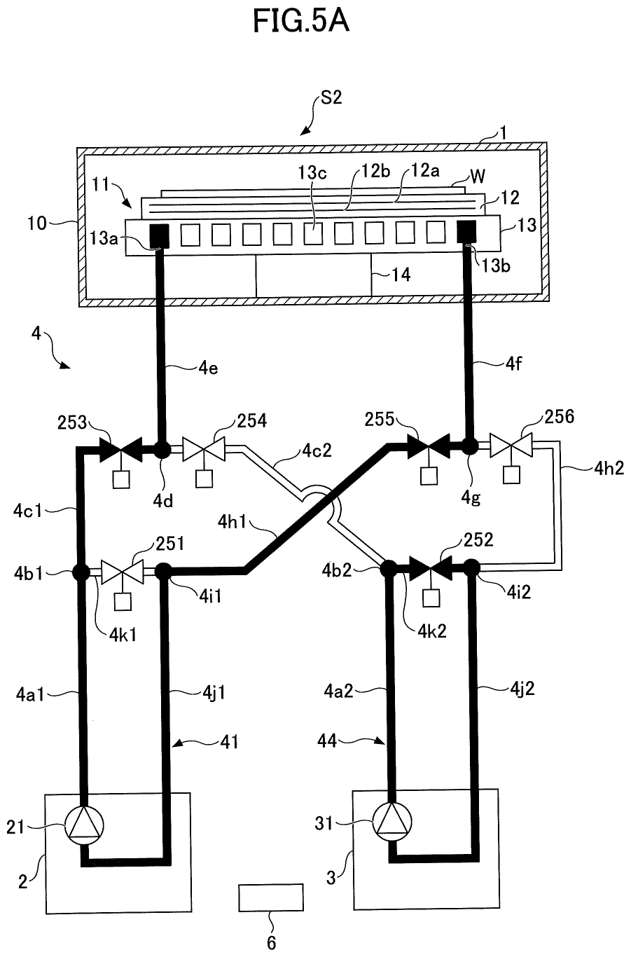

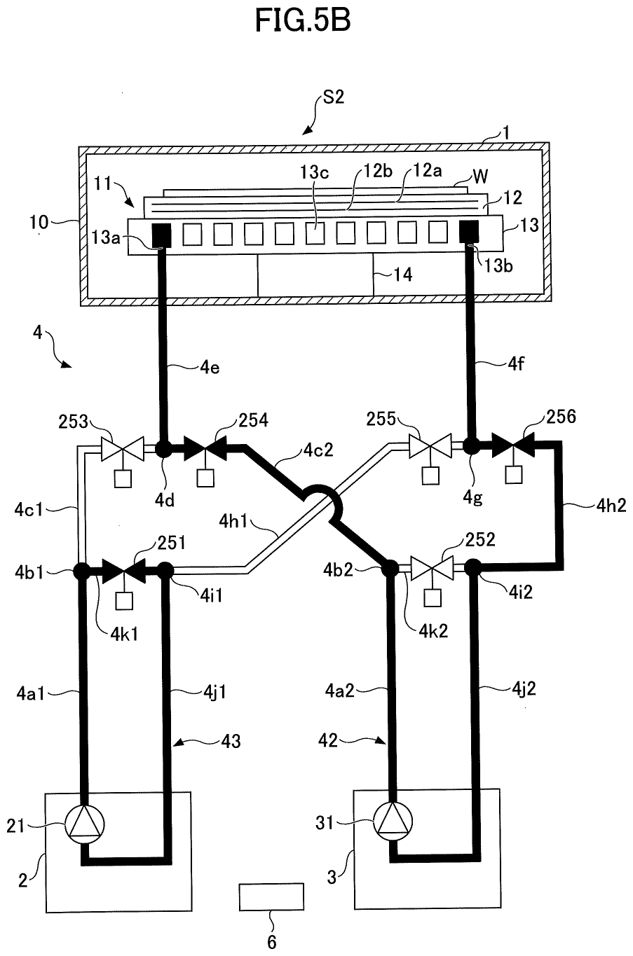

FIGS. 5A and 5B are diagrams illustrating a configuration of a temperature controlling apparatus S2 in a second reference example. FIG. 5A illustrates a first mode operation, and FIG. 5B illustrates a second mode operation.

In the second reference example, the temperature controlling apparatus S2 includes on-off valves 251, 252, 253, 254, 255, and 256, instead of the three-way valves 51, 52, and 53 of the temperature controlling apparatus S according to the first embodiment. Other configurations are similar to the temperature controlling apparatus S; accordingly, duplicative explanations will be omitted for the configuration of the temperature controlling apparatus S2.

The on-off valve 251 is disposed in a flow path 4k1, and the on-off valve 252 is disposed in a flow path 4k2. The on-off valve 253 is disposed in a flow path 4c1, and the on-off valve 254 is disposed in a flow path 4c2. The on-off valve 255 is disposed in a flow path 4h1, and the on-off valve 256 is disposed in a flow path 4h2.

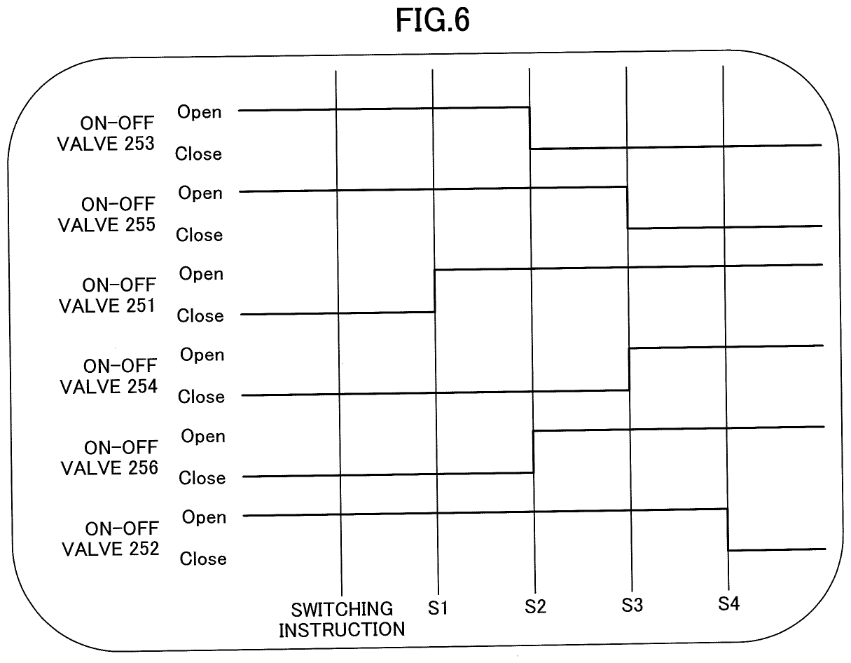

FIG. 6 is a time chart for example of a switching process by the temperature controlling apparatus S2 in the second reference example.

Upon receiving a switching instruction, in step S1, a control device 6 causes the on-off valve 251 to switch from off (close) to on (open).

In step S2, the control device 6 causes the on-off valve 253 to switch from on (open) to off (close). The control device 6 also causes the on-off valve 256 to switch from off (close) to on (open).

In step S3, the control device 6 causes the on-off valve 255 to switch from on (open) to off (close). The control device 6 also causes the on-off valve 254 to switch from off (close) to on (open).

In step S4, the control device 6 causes the on-off valve 252 to switch from on (open) to off (close).

As described above, in a manner such that the switching process is performed in order to avoid water hammer caused by a blockage in flow paths along which pumps 21 and 31 are arranged, the four steps are required to be taken by the temperature controlling apparatus S2 in the second reference example.

With respect to the temperature controlling apparatus S according to the first embodiment, the number of valves (which include a three-way valve and an on-off valve) can be reduced, compared to the temperature controlling apparatuses S1 and S2 in the first and second reference examples. Additionally, the number of steps taken for switching of valves in order to avoid blockage of one or more given flow paths can be reduced. In this case, a temperature of a heat medium that is supplied to the member flow path 13c can be quickly adjusted.

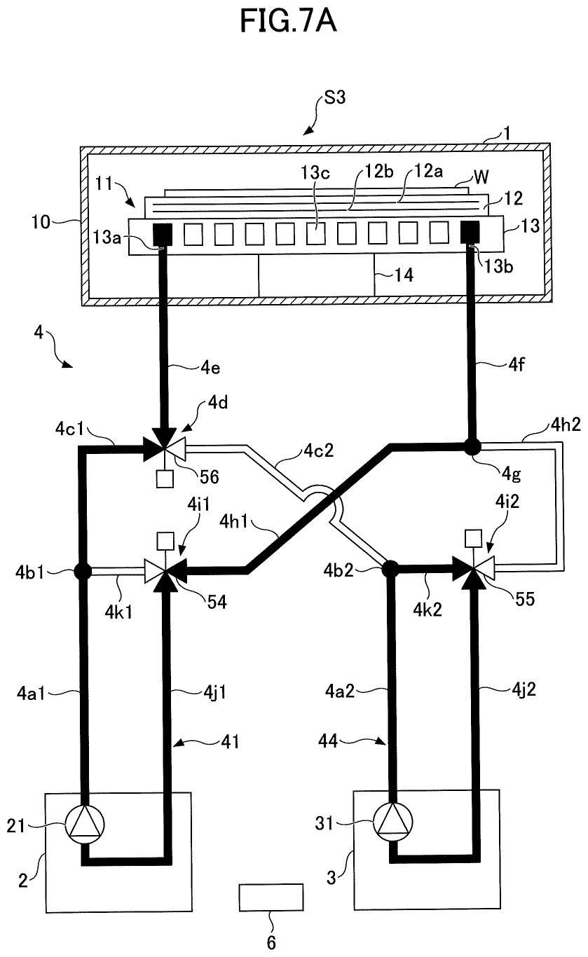

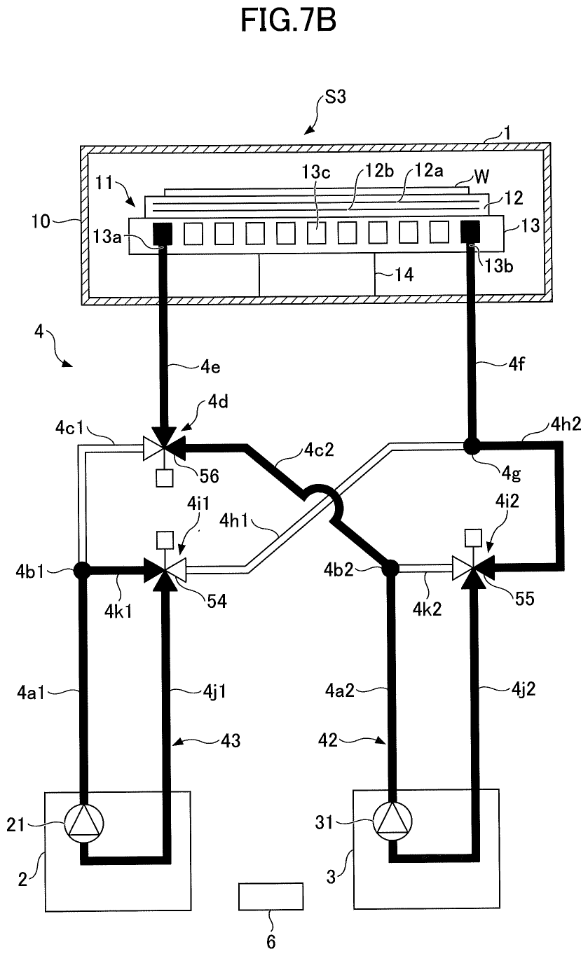

Hereafter, a temperature controlling apparatus S3 according to a second embodiment will be described with reference to FIGS. 7A and 7B. FIGS. 7A and 7B are diagrams illustrating an example of a configuration of the temperature controlling apparatus S3 according to the second embodiment. FIG. 7A illustrates an example of engaging a first mode operation, and FIG. 7B illustrates an example of engaging a second mode operation.

The temperature controlling apparatus S3 according to the second embodiment includes a processing device 1, a first chiller 2, a second chiller 3, and a flow path 4. The temperature controlling apparatus S3 includes three-way valves 54, 55, and 56 that are disposed in the flow path 4, and includes a control device 6.

In the second embodiment, the temperature controlling apparatus S3 includes the three-way valves 54, 55, and 56, instead of the three-way valves 51, 52, and 53 of the temperature controlling apparatus S according to the first embodiment. Other configurations are similar to the temperature controlling apparatus S; accordingly, duplicative explanations will be omitted for the configuration of the temperature controlling apparatus S3.

The three-way valve 54 has two inlet ports and one outlet port. The three-way valve 54 is configured such that, as a degree of opening of one inlet port increases, a degree of opening of the other inlet port is decreased. The three-way valves 55 and 56 each have the same configuration as the three-way valve 54.

The three-way valve 54 is disposed at a coupler 4i1. In this case, with respect to the three-way valve 54, one inlet port as a first inlet port is coupled to a flow path 4h1; another inlet port as a second inlet port is coupled to a flow path 4k1; and an outlet port is coupled to a flow path 4j1. In such a manner, the three-way valve 54 can switch a flow of a first temperature-controlled medium, between a first flow path 41 and a third flow path 43.

The three-way valve 55 is disposed at a coupler 4i2. In this case, with respect to the three-way valve 55, one inlet port as a first inlet port is coupled to a flow path 4h2; another inlet port as a second inlet port is coupled to a flow path 4k2; and an outlet port is coupled to a flow path 4j2. In such a manner, the three-way valve 55 can switch a flow of a second temperature-controlled medium, between a second flow path 42 and a fourth flow path 44.

The three-way valve 56 is disposed at a coupler 4d. In this case, with respect to the three-way valve 56, one inlet port as a first inlet port is coupled to a flow path 4c1; another inlet port as a second inlet port is coupled to a flow path 4c2; and an outlet port is coupled to a flow path 4e. In such a manner, the three-way valve 56 can switch a flow, between the first flow path 41 of a first temperature-controlled medium and the second flow path 42 of a second temperature-controlled medium, so that a corresponding temperature-controlled medium flows to the medium flow path 13c.

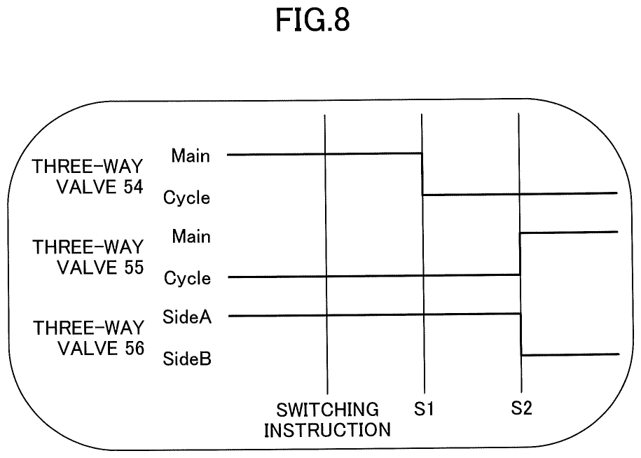

Hereafter, a switching process in the temperature controlling apparatus S3 according to the second embodiment will be described with reference to FIG. 8. FIG. 8 is a time chart for explaining an example of the switching process by the temperature controlling apparatus S3 according to the second embodiment.

In this description, a case where a state (see FIG. 7A) in which a first temperature-controlled medium is supplied to the member flow path 13c is changed to a state (see FIG. 7B) in which a second temperature-controlled medium is supplied will be described as an example.

Upon receiving a switching instruction, in step S1, the control device 6 causes the three-way valve 54 to switch a flow from a first flow path 41 (main) to a third flow path 43 (cycle).

In step S2, the control device 6 causes the three-way valve 55 to switch a flow from a fourth flow path 44 (cycle) to a second flow path 42 (main). The control device 6 also causes the three-way valve 56 to switch a flow from the first flow path 41 (side A) to the second flow path 42 (side B).

As described above, in the temperature controlling apparatus S3 according to the second embodiment, with the two steps being taken, water hammer caused by a blockage in flow paths along which pumps 21 and 31 are arranged can be avoided.

As described above, with respect to the temperature controlling apparatus S3 according to the second embodiment, the number of valves (which includes total of three-way valves and on-off valves) can be reduced, compared to the temperature controlling apparatuses S1 and S2 in the first and second reference examples. Additionally, the number of steps taken for switching of valves in order to avoid blockage of one or more given flow paths can be reduced. In this case, a temperature of a heat medium that is supplied to the member flow path 13c can be quickly adjusted.

The preferred embodiments have been described above. However, the present disclosure is not limited to the above embodiments, and various modifications, alternatives, or the like can be made within departing from the scope of the present disclosure. Also, the features described separately may be combined as long as there is no technical inconsistency.

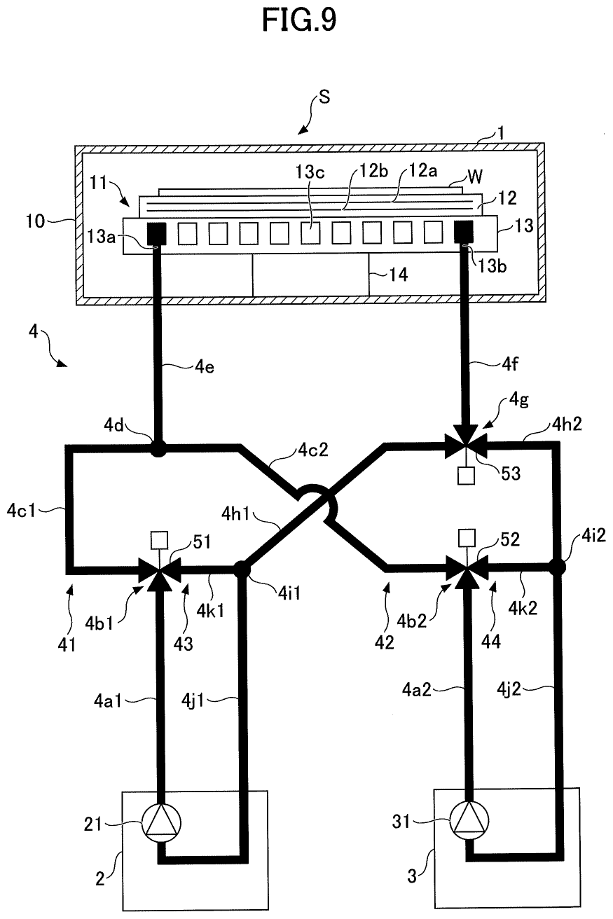

FIG. 9 is a diagram illustrating an example of a temperature controlling apparatus S according to the first embodiment in which a third mode operation is engaged.

As illustrated in FIG. 9, the temperature controlling apparatus S according to the first embodiment may adjust a degree of opening of each of the three-way valves 51, 52, and 53 such that, a portion of a first temperature-controlled medium flows along a first flow path 41; the remainder of the first temperature-controlled medium is cycled through a third flow path 43; a portion of a second temperature-controlled medium flows along a second flow path 42; and the remainder of the second temperature-controlled medium is cycled through a fourth flow path 44. Thereby, a temperature of a heat medium that is supplied to a member flow path 13c can be adjusted.

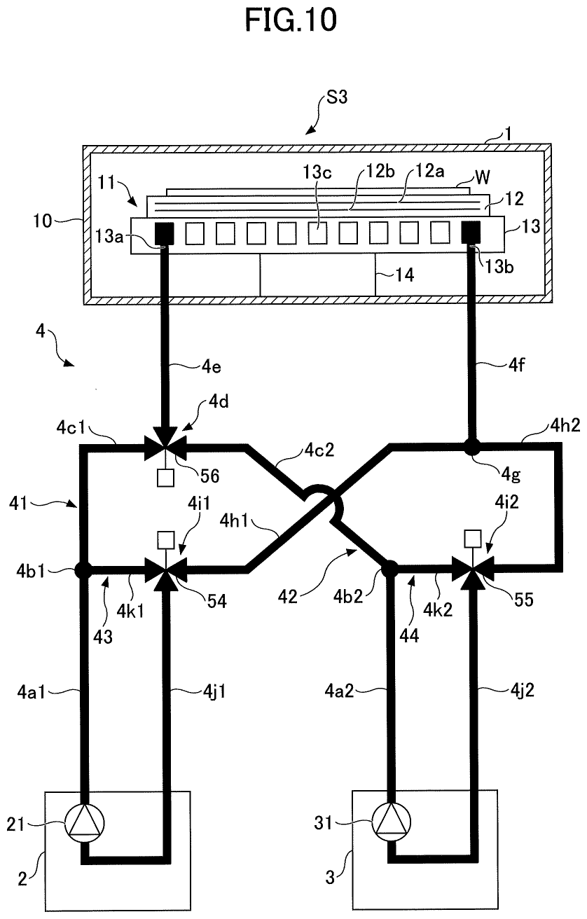

FIG. 10 is a diagram illustrating an example of a temperature controlling apparatus S3 according to the second embodiment in which a third mode operation is engaged.

As in a similar manner to FIG. 9, in FIG. 10, the temperature controlling apparatus S3 according to the second embodiment may adjust a degree of opening of each of the three-way valves 54, 55, and 56 such that, a portion of a first temperature-controlled medium flows along a first flow path 41; the remainder of the first temperature-controlled medium is cycled through a third flow path 43; a portion of a second temperature-controlled medium flows along a second flow path 42; and the remainder of the second temperature-controlled medium is cycled through a fourth flow path 44. Thereby, temperatures of a heat medium that is supplied to a member flow path 13c can be adjusted.

The processing device 1 in the present disclosure is applicable to any type of substrate processing devices such as capacity coupled plasma (CCP), inductively coupled plasma (ICP), radial line slot antenna (RLSA), electron cyclotron resonance plasma (ECR), and helicon wave plasma (HWP).

What is claimed is:

1. A temperature controlling apparatus comprising:
a member having a member flow path within the member;
a first temperature controller configured to control a temperature of a first temperature-controlled medium to a first temperature;
a second temperature controller configured to control a temperature of a second temperature-controlled medium to a second temperature, the second temperature differing from the first temperature;
a first flow path of the first temperature-controlled medium, between the member flow path and the first temperature controller;
a second flow path of the second temperature-controlled medium, between the member flow path and the second temperature controller;
a third flow path of the first temperature-controlled medium that flows to the first temperature controller, without using the member flow path;
a fourth flow path of the second temperature-controlled medium that flows to the second temperature controller, without using the member flow path;
a first three-way valve configured to switch a flow between the first flow path and the third flow path;
a second three-way valve configured to switch a flow between the second flow path and the fourth flow path; and
a third three-way valve configured to switch a flow between the first flow path and the second flow path.

2. The temperature controlling apparatus according to claim 1, wherein the member path flow includes an inlet and an outlet,
wherein the first three-way valve is disposed at a coupler of the first flow path and the third flow path and in a flow path from the first temperature controller to the inlet of the member flow path,
wherein the second three-way valve is disposed at a coupler of the second flow path and the fourth flow path and in a flow path from the second temperature controller to the inlet of the member flow path, and
wherein the third three-way valve is disposed at a coupler of the first flow path and the second flow path and in a flow path from the outlet of the member flow path.

3. The temperature controlling apparatus according to claim 1, wherein the member flow path includes an inlet and an outlet,
wherein the first three-way valve is disposed at a coupler of the first flow path and the third flow path and in a flow path from the outlet of the member flow path to the first temperature controller,
wherein the second three-way valve is disposed at a coupler of the second flow path and the fourth flow path and in a flow path from the outlet of the member flow path to the second temperature controller, and
wherein the third three-way valve is disposed at a coupler of the first flow path and the second flow path and in a flow path to the inlet of the member flow path.

4. The temperature controlling apparatus according to claim 1, wherein the member is a stage for mounting a substrate.

5. The temperature controlling apparatus according to claim 2, wherein the member is a stage for mounting a substrate.

6. The temperature controlling apparatus according to claim 3, wherein the member is a stage for mounting a substrate.

7. The temperature controlling apparatus according to claim 1, further comprising a controller configured to control switching of the first three-way valve, the second three-way valve, and the third three-way valve such that, after switching of the first three-way valve, the second three-way valve and the third three-way valve are switched.

8. The temperature controlling apparatus according to claim 2, further comprising a controller configured to control switching of the first three-way valve, the second three-way valve, and the third three-way valve such that, after switching of the first three-way valve, the second three-way valve and the third three-way valve are switched.

9. The temperature controlling apparatus according to claim 3, further comprising a controller configured to control switching of the first three-way valve, the second three-way valve, and the third three-way valve such that, after switching of the first three-way valve, the second three-way valve and the third three-way valve are switched.

10. The temperature controlling apparatus according to claim 4, further comprising a controller configured to control switching of the first three-way valve, the second three-way valve, and the third three-way valve such that, after switching of the first three-way valve, the second three-way valve and the third three-way valve are switched.

11. A method of controlling a temperature controlling apparatus comprising:
switching a first three-way valve of the temperature controlling apparatus, the first three-way valve being configured to switch a flow between a first flow path and a third flow path, the temperature controlling apparatus including:
a member having a member flow path within the member;
a first temperature controller configured to control a temperature of a first temperature-controlled medium to a first temperature;
a second temperature controller configured to control a temperature of a second temperature-controlled medium to a second temperature, the second temperature differing from the first temperature;
the first flow path of the first temperature-controlled medium, between the member flow path and the first temperature controller;
a second flow path of the second temperature-controlled medium, between the member flow path and the second temperature controller;
the third flow path of the first temperature-controlled medium that flows to the first temperature controller, without using the member flow path;
a fourth flow path of the second temperature-controlled medium that flows to the second temperature controller, without using the member flow path;
a second three-way valve configured to switch a flow between the second flow path and the fourth flow path; and
a third three-way valve configured to switch a flow between the first flow path and the second flow path, and
after switching the first three-way valve, switching the second three-way valve and the third three-way valve.
